(19) United States
(12) Patent Application Publication
(10) Pub. No.: US 2012/0104418 A1
(43) Pub. Date: May 3, 2012

(54) LIGHT-EMITTING MODULE AND ALTERNATING CURRENT LIGHT-EMITTING DEVICE

(75) Inventor: Kun-Chuan LIN, Taipei (TW)

(73) Assignee: KUN HSIN TECHNOLOGY INC., Taipei (TW)

(21) Appl. No.: 12/983,026

(22) Filed: Dec. 31, 2010

(30) Foreign Application Priority Data
Oct. 28, 2010 (TW) 099136879

(51) Int. Cl. H01L 33/50; H01L 33/60

(52) U.S. Cl. 257/88; 257/98; 257/E33.056; 257/E33.061

(57) ABSTRACT

A light-emitting module is provided, including a heat sink and a plurality of insulating layers disposed over the heat sink. A plurality of light-reflective layers is disposed over one of the insulating layers, respectively, wherein the light-reflective layers comprise a plurality of light-reflective inclined surfaces. A plurality of conductive layers is disposed over one of the light-reflective layers, respectively. A light-emitting diode (LED) chip is disposed over the heat sink. A plurality of bonding wires is provided, connecting the LED chip with the conductive layers. A transparent housing is disposed over the LED chip. A phosphor layer is disposed over a surface of the transparent housing facing the heat sink, and does not physically contact the LED chip.

### CROSS REFERENCE TO RELATED APPLICATIONS

This Application claims priority of Taiwan Patent Application No. 99136879, filed on Oct. 28, 2010, the entirety of which is incorporated by reference herein.

### BACKGROUND OF THE INVENTION

1. Field of the Invention

The present invention relates to light-emitting devices, and in particular to a light-emitting module using light-emitting diodes (LEDs) not contacting phosphor materials and an alternating current (AC) light-emitting device using the same.

2. Description of the Related Art

White light-emitting diodes (LEDs) are point light sources that are packaged as a matrix LED for illumination, having advantages such as smaller sizes.

White light is produced by combining at least two chromatic lights with different wavelengths, such as a blue and yellow light of complementary color or a blue, green and red light.

The following are two types of white light LED modules which are commercially available.

One type of white light LED module uses a blue LED to excite yellow phosphors to produce white light. The blue LED is coated by an optical resin mixed with yellow phosphors. The blue LED emits blue light and the yellow phosphors are excited by the blue light emitted from the blue LED to produce yellow light, and a portion of blue light mixes with the generated yellow light to form a white light with complementary colors; and

The other type of white light LED module uses an ultraviolet (UV) LED to excite multi-color phosphors mixed in transparent optical resin having a specific ratio between blue, green and red phosphors. The UV LED is coated by an optical resin mixed with a specific ratio between blue, green and red phosphors, and the UV LED emits UV light, and the multi-color phosphors are excited by the UV light emitted from the UV LED to produce white light, similar to the method for generating white light of fluorescent lamps.

However, in above white light LED modules, since the transparent optical resin mixed with phosphors with predetermined colors physically contacts the LED chip, heat generated from the LED chip during operation of the white light LED module affects the transparent optical resin mixed with phosphors with predetermined colors. Thus, the transparent optical resin mixed with phosphors is degraded. Moreover, phosphors have conversion efficiency issues and also generates heat, thereby affecting efficiency and lifetime of the LED chip. Further, since the LED chip is typically disposed over a lead frame of a small footprint and is covered by the above-described transparent optical resin, heat dissipation of the heat generated by the LED chip by the lead frame is limited. Therefore, as the operation time of the light emitting module increases, heat accumulated therein will cause wavelength shift of the light emitted from the LED chip therein, and the transparent optical resin will degrade, thereby affecting the white light emitting performances of a light-emitting module made therefrom.

### BRIEF SUMMARY OF THE INVENTION

Light-emitting modules and alternating current (AC) light-emitting devices are provided.

An exemplary light-emitting module comprises a heat sink and a plurality of insulating layers disposed over the heat sink. A plurality of light-reflective layers is disposed over one of the insulating layers, respectively, wherein the light-reflective layers comprise a plurality of light-reflective inclined surfaces. A plurality of conductive layers is disposed over one of the light-reflective layers, respectively. A connection layer is disposed over the heat sink, wherein the connection layer has a coefficient of thermal conductivity of greater than 2. A light-emitting diode (LED) chip is disposed over the connection layer. A plurality of bonding wires is provided, connecting the LED chip with the conductive layers. A transparent housing is disposed over the LED chip. A phosphor layer is disposed over a surface of the transparent housing facing the heat sink, wherein the phosphor layer does not physically contact the LED chip.

Another exemplary light-emitting module comprises a heat sink and a plurality of connection layers disposed over various portions of the heat sink, wherein the connection layers have a coefficient of thermal conductivity of greater than 2. A plurality of insulating layers, light-reflective layers, and conductive layers, is alternating disposed over various portions of the heat sink with the connection layers, wherein the light-reflective layers comprise a plurality of light-reflective inclined surfaces. A plurality of light-emitting diode (LED) chips is disposed over one of the connection layers, respectively. A plurality of bonding wires is provided, connecting the LED chips in series with the conductive layers. A transparent housing is disposed over the LED chips. A phosphor layer is disposed over a surface of the transparent housing facing the LED chips, wherein the phosphor layer does not physically contact the LED chip.

Yet another exemplary light-emitting module comprises a heat sink and a plurality of connection layers disposed over various portions of the heat sink, wherein the connection layers have a coefficient of thermal conductivity of greater than 2. A plurality of light-emitting diode (LED) chips is disposed over one of the connection layers, respectively. A plurality of bonding wires is provided, connecting the LED chips in series. A transparent housing is disposed over the LED chips. A phosphor layer is disposed over a surface of the transparent housing facing the LED chips, wherein the phosphor layer does not physically contact the LED chip.

An exemplary alternating current (AC) light emitting device comprises the light-emitting module as described above and a bridge rectifier coupled to the light-emitting module, wherein the bridge rectifier is coupled to a current-limiting resistor and an alternating current power supply during operation.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 shows a light emitting module according to an embodiment of the invention;

FIG. 2 shows a light emitting module according to another embodiment of the invention;

FIG. 3 shows a light emitting module according to yet another embodiment of the invention;

FIG. 4 shows a light emitting module according to another embodiment of the invention;

FIG. 5 shows a light emitting module according to yet another embodiment of the invention;

FIG. 6 illustrate a light emitting module according to another embodiment of the invention; and

FIG. 7 illustrate an alternate current (AC) light emitting device according to an embodiment of the invention, utilizing the light emitting module illustrated in FIGS. 3, 4, 5 or 6.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

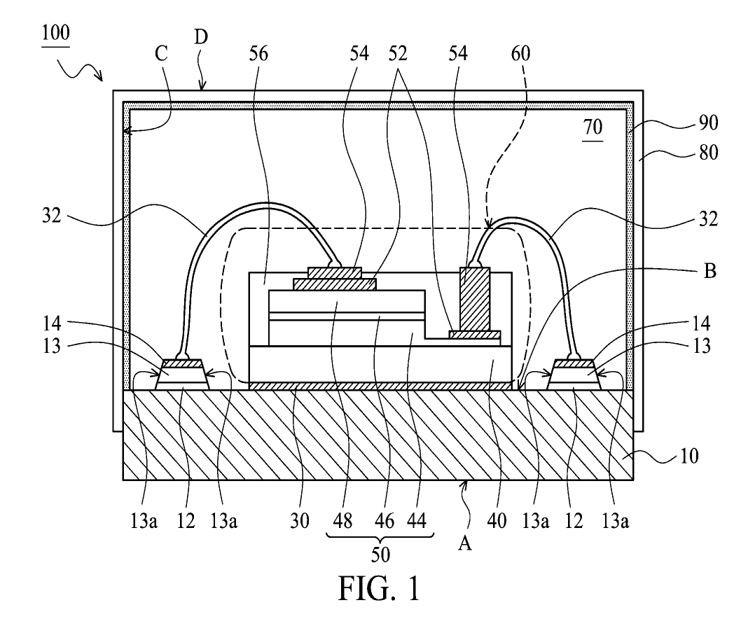

FIG. 1 shows an exemplary light-emitting module 100, comprising main components such as a heat sink 10, a light-emitting diode (LED) chip 60, a transparent housing 80, and a phosphor layer 90 disposed over a surface of the transparent housing 80.

As shown in FIG. 1, the heat sink 10 in the exemplary light-emitting module 100 is illustrated as a planar substrate having opposite planar surfaces A and B, and the LED chip 60 is disposed over the surface B of the heat sink 10. Herein, a connection layer 30 is disposed between the heat sink 10 and the LED chip 60. Through the use of the connection layer 30, the LED chip 60 can be stably disposed over the surface B of the heat sink 10 by, for example, a eutectic bonding or adhesion method. Moreover, a plurality of insulating layers 12 is disposed over the heat sink 30, and a conductive layer 14 is respectively disposed over one of the insulating layers 12 to function as a conductive line or a conductive bonding pad. A light-reflective layer 13 is disposed between the insulating layer 12 and the conductive layer 14. The light-reflective layer 13 comprises materials having surfaces capable of reflecting light, such as metal, metal alloy, metal oxide, or plastic surfaces. The light-reflective layer 13 is formed with a trapezoid cross section and a plurality of light-reflective inclined surfaces 13a to thereby reflect light emitted from the LED chip 60.

In one embodiment, the LED chip 60 comprises an epitaxial substrate 40. The epitaxial substrate 40 can be formed of insulating materials such as sapphire (Al₂O₃), silicon substrate or silicon carbide (SiC) substrate, although it may also be formed of other materials having characteristics close to the characteristics of the LED formed thereon (which may comprise group-III and group-V elements, which is also known as III-V compound semiconductor materials). In addition, a light-emitting diode (LED) element 50 is formed over a portion of the epitaxial substrate 40, comprising a plurality of film layers 44, 46, and 48 sequentially stacked over the epitaxial substrate 40, wherein the film layer 44 is a first group-III nitride (III-nitride) layer doped with a first impurity of a first conductivity type, the film layer 46 is a multiple quantum well (MQW) layer, and the film layer 48 is a second III-nitride layer doped with a second impurity of a second conductivity type opposite the first conductivity type. In addition, a transparent electrode layer 52 is disposed over the second III-nitride layer 46 and a portion of the first III-nitride layer 44. A conductive contact 54 is respectively disposed over the transparent electrodes 52 to function as a contact node for electrically connecting to the LED chip 60 or other components. Moreover, the LED chip 60 further comprises a transparent insulating layer 56 substantially covering the conductive contacts 54, the transparent electrodes 52, and the LED element 52 and merely a portion of the conductive layers 54 is partially exposed. Through the use of the transparent passivation layer 56, the components in the LED chip 60 can be prevented from contacting the surround areas and causing oxidization, and a surface of the transparent passivation layer 56 can be a smooth surface or a rough surface processed by a roughing treatment.

In one embodiment, the LED element 50 may comprise, for example, an n-GaN layer (GaN doped with an n-type impurity) 44, a multiple quantum well (MQW) layer 46, and a p-GaN layer (GaN doped with a p-type impurity) 48. The MQW layer 46 may be formed of, for example, InGaN, and act as an active layer for emitting light. Formations of the above layers 44, 46, and 48 are known in the art, and hence are not disclosed in detail herein.

In one embodiment, formation methods of the above layers 44, 46, and 48 may include epitaxial growth. In addition, the transparent electrode layer 52 can be formed of transparent conductive materials such as indium tin oxide (ITO), Zinc oxide (ZnO), or other transparent conductive materials.

As shown in FIG. 1, the conductive contacts 54 formed over the LED chip 60 are electrically connected with one of the conductive layers 14 formed over the heat sink 10 by a bonding wire 32. The transparent housing 80 is disposed over the LED chip 60 to substantially cover the surface B of the heat sink 10 and components formed thereover, thereby defining a sealed space 70 between the transparent housing 80 and the heat sink 10. Herein, the transparent housing 80 has opposite surfaces C and D. The surface C is a surface facing the LED chip 60 and the heat sink 10, and a phosphor layer 90 is formed over the surface C of the transparent housing 80.

In efforts for white light illumination, the LED chip 60 used in the light emitting module 100 can be LED chips capable of emitting lights with a wavelength band between green light and UV light. Thus, since blue light may be emitted from the LED chip 60, the phosphor layer 90 may comprises epoxy resin or silicone materials mixed with YAG phosphors, TAG phosphors, or BOS phosphors. Also, since blue-green light may be emitted from the LED chip, the phosphor layer 90 may comprises epoxy resin or silicone materials mixed with sulfides or mixed with SrS:Eu phosphors. Further, since ultraviolet light may be emitted from the LED chip 60, the phosphor may comprise epoxy resin or silicone materials mixed with blue, yellow and red phosphors.

In one embodiment, the heat sink 10 may comprises metals such as Al, Cu, Fe, Ag, Au, alloys thereof, or other alloys, graphite powders, diamond powders, or other high thermal conductive materials, having a coefficient of thermal conductivity of about 10-6000, and the connection layer 30 may comprise conductive materials such as silver glues (having a coefficient of thermal conductivity of about 4), graphite glues (having a coefficient of thermal conductivity of about 8), diamond powder glues (having a coefficient of thermal conductivity of about 30), other metal powder glues or metal alloys, having a coefficient of thermal conductivity of greater than 2, preferably of about 10-3000. The transparent passivation layer 56 may comprise insulating materials such as silicon dioxide, silicon nitride, silicon, epoxy or other transparent materials. The sealed space 70 may be filled with nitrogen, helium, argon, dry air, gases which can reduce oxidation or is a vacuum. The transparent housing 80 may comprise glass, arcylic acid resin, silicon, epoxy resin, plastic or other transparent materials.

In the light emitting module 100 shown in FIG. 1, since the LED chip 60 does not physically contact the phosphor layer 90, and the LED chip 60 is isolated from the phosphor layer 90 by the sealed space 70, such that heat generated by the LED chip 60 during operation thereof will not degrade the phosphor layer 90. In addition, since the LED chip 60 is disposed over the heat sink 10 through the use of the connection layer 30 which has good thermal conductivity, heat generated by the LED chip 60 during operation thereof can be dissipated by the connection layer 30 and the heat sink 10 having good thermal conductivity, thereby reducing heat accumulation in the light-emitting module 100. White light illumination performances and reliability of the light-emitting module 100 are thus improved.

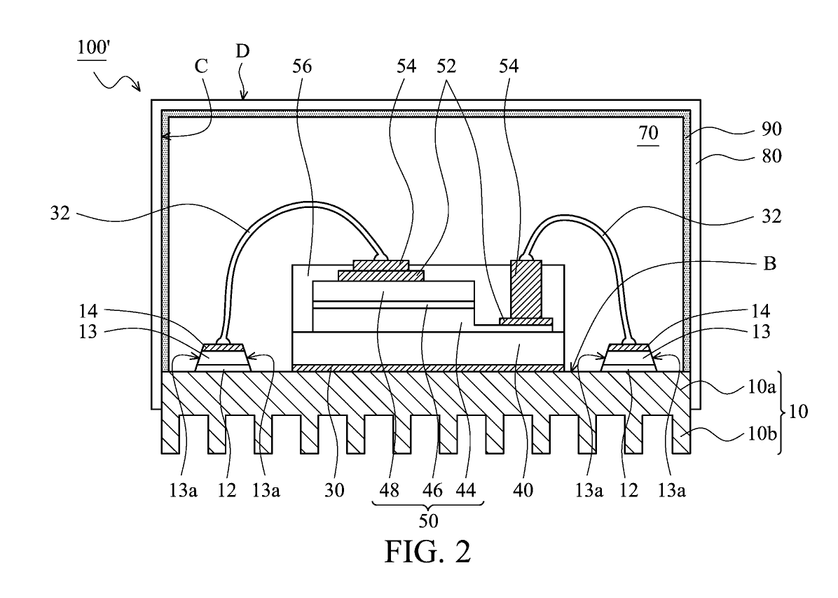

In FIG. 2, another exemplary light-emitting module 100′ is illustrated. Herein, the light-emitting module 100′ is substantially the same with the light-emitting module 100 shown in FIG. 1, and the heat sink 10 in the light-emitting module 100′ has been modified. For the purposes of clarity and simplicity, same components in these embodiments are represented with the same numbers.

As shown in FIG. 2, in this embodiment, the heat sink 10 merely has a planar surface B for disposing main components such as the LED chip 60 thereover, and the surface A of the heat sink 10 (referring to FIG. 1) is processed by methods such as micromachining or etching to form a plurality of separated fins 10b in the heat sink 10, and portions of the heat sink 10 not processed by the above method are illustrated as a planar portion 10a, and the fins 10b connecting the planar portion 10a and the planar portion 10a form the heat sink 10 of this embodiment.

In this embodiment, due to formation of the fins 10b, the heat sink 10 shown in FIG. 2 can more effectively dissipate heat generated by the LED chip 60 during operation thereof than the heat sink 10 shown in FIG. 1, thereby reducing heat accumulation in the light-emitting module 100′. White light emitting performance and reliability of the light-emitting module 100′ can be thus improved.

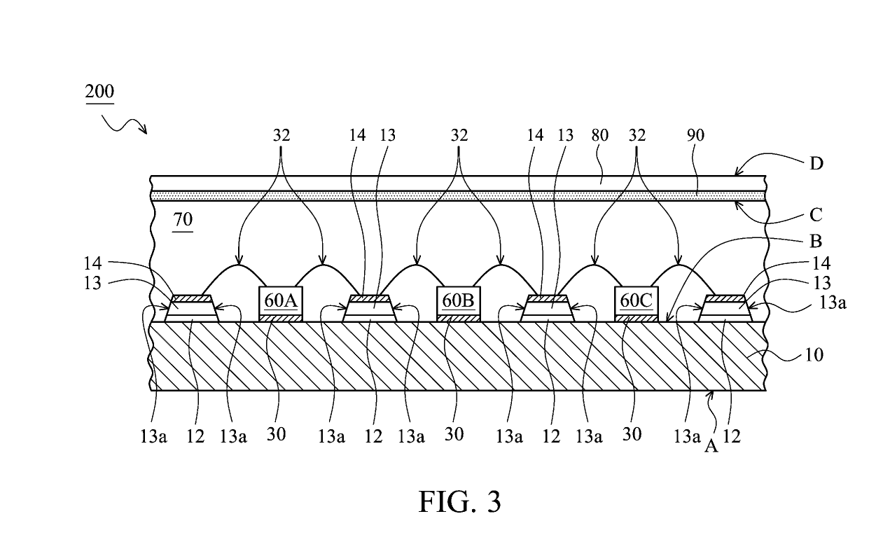

In FIG. 3, another exemplary light-emitting module 200 is illustrated. Herein, the light-emitting module 200 is substantially the same with the light-emitting module 100 shown in FIG. 1, and installation of the LED chip 60 and the conductive layers over the heat sink 10 are modified. For the purposes of clarity and simplicity, same components in these embodiments are represented with the same numbers.

As shown in FIG. 3, in this embodiment, a plurality of LED chips 60A, 60B and 60C and a plurality of conductive layers 14 are alternatively disposed over the surface B of the heat sink 10. Similarly, an insulating layer 12 and a light reflection layer 13 are sequentially formed between the conductive layer 14 and the heat sink 10, and the LED chips 60A, 60B, and 60C, are directly disposed over the heat sink 10 through the connection layer 30 having good thermal conductivity. As shown in FIG. 3, through alternatively disposing the LED chips 60A, 60B, and 60C, and the conductive layers 14, the LED chips 60A, 60B, and 60C can be electrically connected in series with one of the conductive layers 14 by a bonding wire 32, thereby forming an array of LED chips which are electrically connected in series. In this embodiment, the transparent housing 80 and the phosphor layer 90 are similar with that illustrated in FIG. 1, and only portions of the transparent housing 80 and the phosphor layer 90 are illustrated in FIG. 3, but the invention is not limited thereto. A sealed space 70 is still defined between the transparent housing 80 and the heat sink 10, having gases such as nitrogen, helium, argon, or dry air filled therein or a vacuum.

In this embodiment, the LED chips 60A, 60B, and 60C of the light-emitting module 200 are disposed over the heat sink 10 through the use of the connection layer 30 which has good thermal conductivity. Thus heat generated by the LED chips 60A, 60B, and 60C during operation thereof can be dissipated by the connection layer 30 and the heat sink 10 having good thermal conductivity, thereby reducing heat accumulation in the light-emitting module 200. White light illumination performances and reliability of the light-emitting module 200 are thus improved.

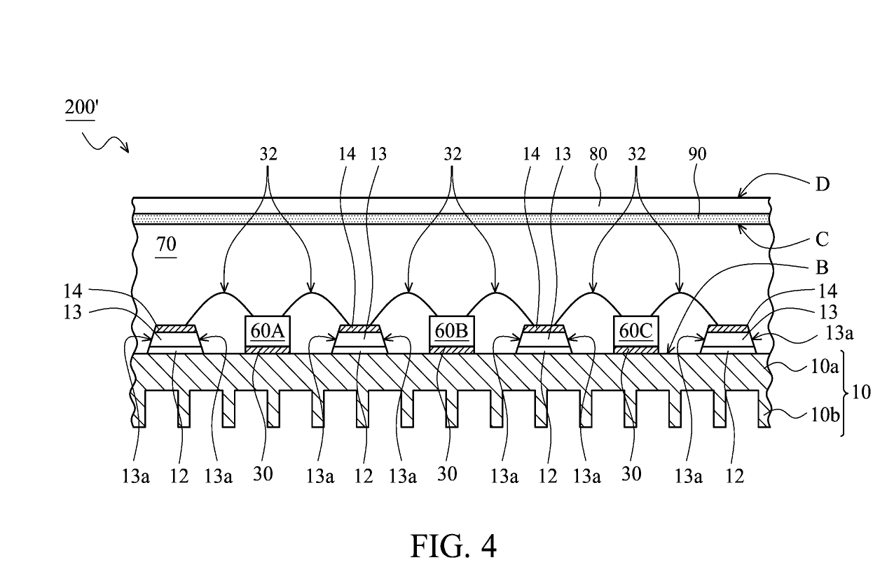

In FIG. 4, another exemplary light-emitting module 200′ is illustrated. Herein, the light emitting module 200′ is substantially the same with the light-emitting module 200 shown in FIG. 3, and the heat sink 10 in the light-emitting module 200′ has been modified. For the purposes of clarity and simplicity, same components in these embodiments are represented with the same numbers.

As shown in FIG. 4, in this embodiment, the heat sink 10 merely has a planar surface B for disposing main components such as the LED chips 60A, 60B, and 60C thereover, and the surface A of the heat sink 10 (referring to FIG. 3) is processed by methods such as micromachining or etching to form a plurality of separated fins 10b in the heat sink 10, and portions of the heat sink 10 not processed by the above method are illustrated as a planar portion 10a in FIG. 4, and the fins 10b connecting the planar portion 10a and the planar portion 10a form the heat sink 10 of this embodiment.

In this embodiment, due to formation of the fins 10b, the heat sink 10 shown in FIG. 4 can more effectively dissipate heat generated by the LED chips 60A, 60B and 60C during operation thereof than the heat sink 10 shown in FIG. 3, thereby reducing heat accumulation in the light-emitting module 200′. White light emitting performance and reliability of the light-emitting module 200′ can be thus improved.

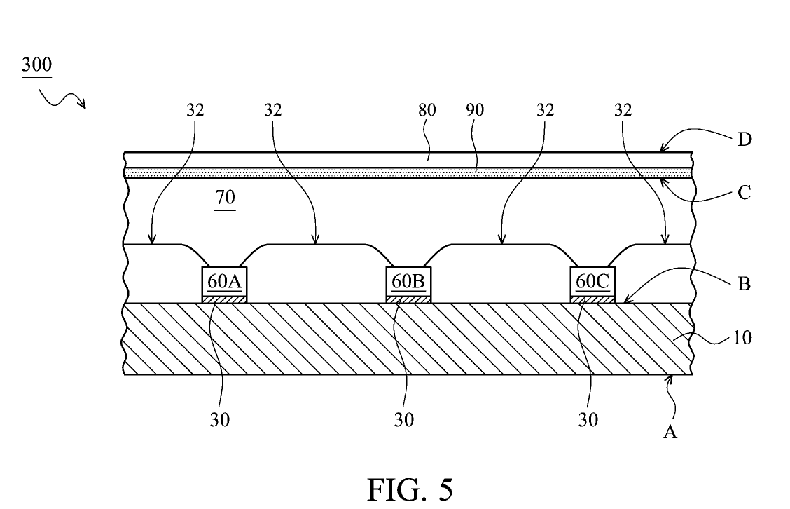

In FIG. 5, another exemplary light-emitting module 300 is illustrated. Herein, the light-emitting module 300 is substantially the same with the light-emitting module 200 shown in FIG. 3, and installation of the conductive layers, the insulating layers, and light-reflective layers over the heat sink 10 are modified. For the purposes of clarity and simplicity, same components in these embodiments are represented with the same numbers.

As shown in FIG. 5, in this embodiment, a plurality of LED chips 60A, 60B and 60C are disposed over the surface B of the heat sink 10 and the conductive layers 14, the light-reflective layers 13 and insulating layers are not disposed over the heat sink. The LED chips 60A, 60B, and 60C, are directly disposed over the heat sink 10 through the connection layer 30 having good thermal conductivity. The conductive contact layers 54 (shown in FIG. 2) of the transparent conductive layer 52 formed over the LED chips 60A, 60B, and 60C are electrically connected in series by a bonding wire 32, thereby forming an array of LED chips which are electrically connected in series. In this embodiment, the transparent housing 80 and the phosphor layer 90 are similar with that illustrated in FIG. 3. A sealed space 70 is still defined between the transparent housing 80 and the heat sink 10, having gases such as nitrogen, helium, argon, or dry air filled therein or a vacuum.

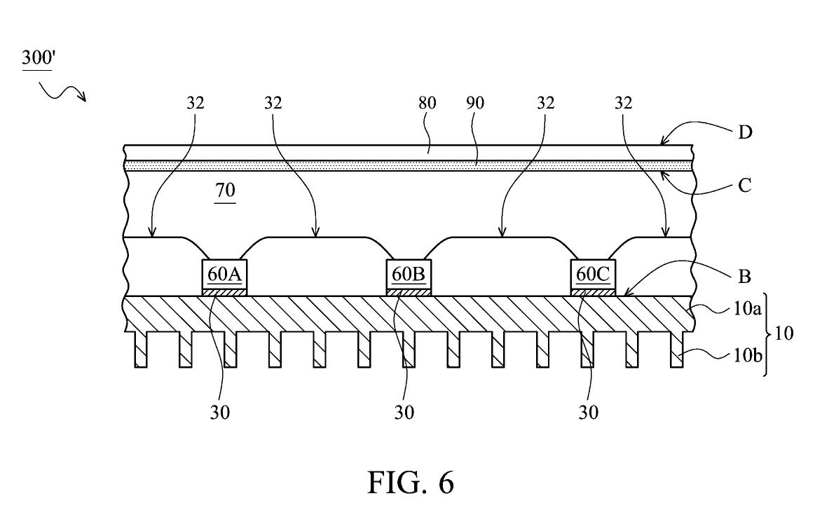

In FIG. 6, another exemplary light-emitting module 300′ is illustrated. Herein, the light emitting module 300′ is substantially the same with the light-emitting module 300 shown in FIG. 5, and the heat sink 10 in the light-emitting module 300′ has been modified. For the purposes of clarity and simplicity, same components in these embodiments are represented with the same numbers.

As shown in FIG. 6, in this embodiment, the heat sink 10 merely has a planar surface B for disposing main components such as the LED chips 60A, 60B, and 60C thereover, and the surface A of the heat sink 10 (referring to FIG. 5) is processed by methods such as micromachining or etching to form a plurality of separated fins 10b in the heat sink 10, and portions of the heat sink 10 not processed by the above method are illustrated as a planar portion 10a in FIG. 6, and the fins 10b connecting the planar portion 10a and the planar portion 10a form the heat sink 10 of this embodiment.

In this embodiment, due to formation of the fins 10b, the heat sink 10 shown in FIG. 6 can more effectively dissipate heat generated by the LED chips 60A, 60B and 60C during operation thereof than the heat sink 10 shown in FIG. 5, thereby reducing heat accumulation in the light-emitting module 300′. White light emitting performance and reliability of the light-emitting module 300′ can be thus improved.

In the above embodiments, the LED element in the LED chips is not limited to that illustrated in FIGS. 1-2. In other embodiments, the LED chips 60, 60A, 60B, and 60C may comprises a plurality of LED elements (e.g. a plurality of LED elements 50 disposed over an epitaxial substrate), and electrical connections between the LED elements are formed by suitable semiconductor fabrication processes, thereby forming single chip type LED chips 60, 60A, 60B, or 60C comprising a plurality of LED elements therein.

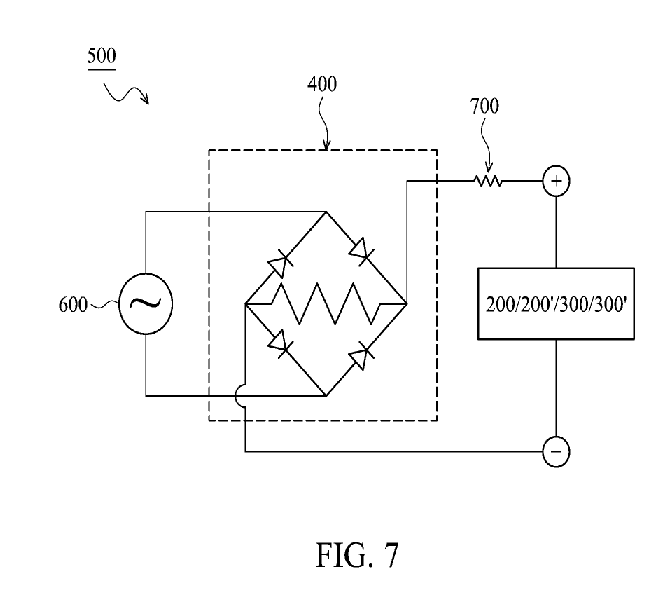

In FIG. 7, an exemplary alternating current (AC) light-emitting device 500 using the light-emitting module illustrated in FIGS. 3, 4, 5 or 6 is illustrated.

Due to the LED chips 60A, 60B, and 60C being connected in series as shown in FIGS. 3-6, an alternating current (AC) light-emitting device can be thus provided through increasing of an amount the LED chips.

As shown in FIG. 7, an alternating current (AC) light-emitting device 500 mainly includes a light-emitting module 200, 200′, 300, or 300′ as shown in FIGS. 3-6, a current limiting resistor 700, and a bridge rectifier 400. As shown in FIG. 7, the bridge rectifier 400 can be coupled to a positive (+) terminal and a negative (−) terminal of the light emitting module 200, 200′, 300, or 300′. During operation of the AC light-emitting device 500, the bridge rectifier 400 is connected to an alternating current (AC) power supply 600, and the AC power supply 600 provides an alternate current voltage of 110V or 220V. The current limiting resistor 700 is coupled to a positive anode of the bridge rectifier 400 and the light emitting module 200, 200′, 300, or 300′ to protect the light emitting module 200, 200′, 300, or 300′ during operation thereof. Amount of the LED chips used in the light emitting module 200, 200′, 300, or 300′ in the AC light-emitting device 500 depends on an operation voltage of the LED chip therein and the alternate current power supply coupled thereto.

In one embodiment, while each of LED chips in the light-emitting module 200, 200′, 300, or 300′ of the AC light-emitting device 500 is provided with an operating voltage of about 3.3 V, and an AC power supply coupled to the AC light emitting device 500 is about 110V, 30-40 of the same LED chips are connected in series to form the light-emitting module 200, 200′, 300, or 300′.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light-emitting module, comprising:
a heat sink;
a plurality of insulating layers disposed over the heat sink;
a plurality of light-reflective layers disposed over one of the insulating layers, respectively, wherein the light-reflective layers comprise a plurality of light-reflective inclined surfaces;
a plurality of conductive layers disposed over one of the light-reflective layers, respectively;
a connection layer disposed over the heat sink, wherein the connection layer has a coefficient of thermal conductivity of greater than 2;
a light-emitting diode (LED) chip disposed over the connection layer;
a plurality of bonding wires connecting the LED chip with the conductive layers;
a transparent housing disposed over the LED chip; and
a phosphor layer disposed over a surface of the transparent housing facing the heat sink, wherein the phosphor layer does not physically contact the LED chip.

2. The light-emitting module as claimed in claim 1, wherein the transparent housing is connected with the heat sink, defining a sealed space between the transparent housing and the heat sink.

3. The light-emitting module as claimed in claim 1, wherein the LED chip comprises:
an epitaxial substrate disposed over the connection layer;
a light-emitting diode (LED) element disposed over a portion of the epitaxial substrate;
a first electrode disposed over a portion of the LED element;
a second electrode disposed over another portion of the LED element;
a conductive contact disposed over the first and second electrodes, respectively; and
a transparent passivation layer covering the epitaxial substrate, the LED element, the first electrode, the second electrode, and the conductive contact, partially exposing a surface of the conductive contact, wherein the transparent passivation layer has a smooth surface or a rough surface.

4. The light-emitting module as claimed in claim 1, wherein the heat sink comprises a planar substrate.

5. The light-emitting module as claimed in claim 1, wherein the heat sink comprises:
a planar portion having opposite third and fourth surfaces, wherein the connection layer and the conductive layer are disposed over the third surface; and
a plurality of fins disposed over the fourth surface of the planar portion.

6. The light-emitting module as claimed in claim 1, wherein the heat sink comprise Al, Cu, Fe, Ag, Au, Mg, alloys thereof, or graphite powders, and the connection layer comprises silver glues, graphite glues, diamond powder glues, carbon powder glues or metal powder containing glues.

7. A light-emitting module, comprising:
a heat sink;
a plurality of connection layers disposed over various portions of the heat sink, wherein the connection layers have a coefficient of thermal conductivity of greater than 2;
a plurality of insulating layers, light-reflective layers, and conductive layers, disposed over various portions of the heat sink, alternating with the connection layers, wherein the light-reflective layers comprise a plurality of light-reflective inclined surfaces;
a plurality of light-emitting diode (LED) chips disposed over one of the connection layers, respectively;
a plurality of bonding wires connecting the LED chips in series with the conductive layers;
a transparent housing disposed over the LED chips; and
a phosphor layer disposed over a surface of the transparent housing facing the LED chips, wherein the phosphor layer does not physically contact the LED chip.

8. The light-emitting module as claimed in claim 7, wherein the transparent housing is connected with the heat sink, defining a sealed space between the transparent housing and the heat sink.

9. The light-emitting module as claimed in claim 7, wherein the LED chips respectively comprise:
an epitaxial substrate disposed over the connection layer;
a light-emitting diode (LED) element disposed over a portion of the epitaxial substrate;
a first electrode disposed over a portion of the LED element;
a second electrode disposed over another portion of the LED element;
a conductive contact disposed over the first and second electrodes, respectively; and
a transparent passivation layer covering the epitaxial substrate, the LED element, the first electrode, the second electrode, and the conductive contact, partially exposing a surface of the conductive contact, wherein the transparent passivation layer has a smooth surface or a rough surface.

10. The light-emitting module as claimed in claim 7, wherein the heat sink comprises:
a planar portion having opposite third and fourth surfaces, wherein the connection layer and the conductive layer are disposed over the third surface; and
a plurality of fins disposed over the fourth surface of the planar portion.

11. The light-emitting module as claimed in claim 7, wherein the heat sink comprise Al, Cu, Fe, Ag, Au, Mg, alloys thereof, or graphite powders, and the connection layer comprises silver glues, graphite glues, diamond powder glues, carbon powder glues or metal powder containing glues.

12. An alternating current light-emitting device, comprising:
a light-emitting module as claimed in claim 7; and
a bridge rectifier coupled to the light-emitting module, wherein the bridge rectifier is coupled to a current-limiting resistor and an alternating current power supply during operation.

13. A light-emitting module, comprising:
a heat sink;
a plurality of connection layers disposed over various portions of the heat sink, wherein the connection layers have a coefficient of thermal conductivity of greater than 2;
a plurality of light-emitting diode (LED) chips disposed over one of the connection layers, respectively;
a plurality of bonding wires connecting the LED chips in series;
a transparent housing disposed over the LED chips; and
a phosphor layer disposed over a surface of the transparent housing facing the LED chips, wherein the phosphor layer does not physically contact the LED chip.

14. The light-emitting module as claimed in claim 13, wherein the transparent housing is connected with the heat sink, defining a sealed space between the transparent housing and the heat sink.

15. The light-emitting module as claimed in claim 13, wherein the LED chips respectively comprise:
an epitaxial substrate disposed over the connection layer;
a light-emitting diode (LED) element disposed over a portion of the epitaxial substrate;
a first electrode disposed over a portion of the LED element;
a second electrode disposed over another portion of the LED element;
a conductive contact disposed over the first and second electrodes, respectively; and
a transparent passivation layer covering the epitaxial substrate, the LED element, the first electrode, the second electrode, and the conductive contact, partially exposing a surface of the conductive contact, wherein the transparent passivation layer has a smooth surface or a rough surface.

16. The light-emitting module as claimed in claim 13, wherein the heat sink comprises a planar substrate.

17. The light-emitting module as claimed in claim 13, wherein the heat sink comprises:
a planar portion having opposite third and fourth surfaces, wherein the connection layer and the conductive layer are disposed over the third surface; and
a plurality of fins disposed over the fourth surface of the planar portion.

18. The light-emitting module as claimed in claim 13, wherein the heat sink comprise Al, Cu, Fe, Ag, Au, Mg, alloys thereof, or graphite powders.

19. The light-emitting module as claimed in claim 13, wherein the connection layer comprises silver glues, graphite glues, diamond powder glues, carbon powder glues or metal powder containing glues.

20. An alternating current light-emitting device, comprising:
a light-emitting module as claimed in claim 13; and
a bridge rectifier coupled to the light-emitting module, wherein the bridge rectifier is coupled to a current-limiting resistor and an alternating current power supply during operation.
